(19) United States
(12) Patent Application Publication
(10) Pub. No.: US 2026/0221394 A1
(43) Pub. Date: Jul. 30, 2026

(54) Apparatus for Extracting Low Energy Ion Beam

(71) Applicant: Applied Materials, Inc., Santa Clara, CA (US)

(72) Inventors: Shengwu Chang, Hamilton, MA (US); Christopher W. Campbell, West Newbury, MA (US); Daniel Distaso, Rowley, MA (US)

(21) Appl. No.: 19/036,868

(22) Filed: Jan. 24, 2025

(51) Int. Cl. H01J 37/32; C23C 14/48

(52) U.S. Cl. CPC H01J 37/32568; C23C 14/48; H01J 2237/3365

(57) ABSTRACT

A workpiece processing system for extracting ion beams at low extraction voltages is disclosed. The workpiece processing system includes an ion source with an extraction plate having an extraction aperture. A ground electrode is rigidly affixed to the extraction plate so as to tightly control the positioning accuracy between the extraction aperture and the aperture in the ground electrode. A suppression electrode is located between the extraction plate and the ground electrode. This suppression electrode is also rigidly mounted so as to create a fixed first gap between the extraction plate and the suppression electrode and a fixed second gap between the suppression electrode and the ground electrode. This system may be operated at extraction voltages as low as 100V and as high as several kV.

### FIELD

Embodiments of the present disclosure relate to methods and apparatus for extracting ion beams at low energies, such as less than 3kV.

### BACKGROUND

Ion implanter systems often utilize an ion source to generate ions. One wall of the ion source is referred to as an extraction plate and includes an extraction aperture. One or more electrodes are disposed outside the extraction aperture. At least one of the electrodes is biased at a negative voltage relative to the ion source to attract positive ions from the ion source through the extraction aperture.

In some systems, there may be at least two electrodes disposed outside the ion source. These two electrodes may be referred to as a suppression electrode and a ground electrode. In other embodiments, there may be more than two electrodes.

Typically, these electrodes are movable relative to the extraction plate so that the gap between the extraction plate and the suppression electrode is variable.

This configuration is optimized for higher extraction voltages, such as 40kV or more. However, this configuration is less effective at lower extraction voltages, such as less than 3 kV. Specifically, the beam focus is not adequate.

Therefore, a system and method that allows the extraction of low energy ion beams would be beneficial. Further, it would be advantageous if this apparatus was low cost and had few moving components.

### SUMMARY

A workpiece processing system for extracting ion beams at low extraction voltages is disclosed. The workpiece processing system includes an ion source with an extraction plate having an extraction aperture. A ground electrode is rigidly affixed to the extraction plate so as to tightly control the positioning accuracy between the extraction aperture and the aperture in the ground electrode. A suppression electrode is located between the extraction plate and the ground electrode. This suppression electrode is also rigidly mounted so as to create a fixed first gap between the extraction plate and the suppression electrode and a fixed second gap between the suppression electrode and the ground electrode. This system may be operated at extraction voltages as low as 100V and as high as several kV.

According to one embodiment, a workpiece processing apparatus is disclosed. The workpiece processing apparatus comprises a plasma chamber having walls and an extraction plate with an extraction aperture; a ground electrode having a ground electrode aperture, physically connected to the extraction plate using ground electrode insulators; and a suppression electrode disposed between the ground electrode and the extraction plate; wherein the suppression electrode is affixed to a surface different from the extraction plate and the ground electrode; such that a distance of a first gap between the extraction plate and the suppression electrode, and a distance of a second gap between the suppression electrode and the ground electrode are both fixed. In some embodiments, the suppression electrode comprises an upper suppression plate and a lower suppression plate with an opening disposed therebetween. In certain embodiments, the upper suppression plate and the lower suppression plate are independently biased. In certain embodiments, a difference in voltage between the upper suppression plate and the lower suppression plate is used to correct for positioning errors in a height direction. In certain embodiments, the plasma chamber is disposed within a vacuum chamber and wherein the upper suppression plate and the lower suppression plate are affixed to walls of the vacuum chamber. In some embodiments, an extraction power supply is used to bias the walls of the plasma chamber, wherein a difference in voltage between the extraction plate and the ground electrode is defined as an extraction voltage and the extraction voltage is between 0.1kV and 3kV. In certain embodiments, the suppression electrode is biased at a voltage between -1kV and -25kV.

According to another embodiment, a workpiece processing apparatus is disclosed. The workpiece processing apparatus comprises a plasma chamber having walls and an extraction plate with an extraction aperture; a ground electrode having a ground electrode aperture, having a fixed spatial relationship to the extraction plate; and a suppression electrode disposed between the ground electrode and the extraction plate; wherein the suppression electrode is affixed to one of the extraction plate and the ground electrode; such that a distance of a first gap between the extraction plate and the suppression electrode, and a distance of a second gap between the suppression electrode and the ground electrode are both fixed. In some embodiments, the ground electrode is affixed to the extraction plate using ground electrode insulators. In certain embodiments, the suppression electrode is affixed to the extraction plate using upper and lower insulators. In certain embodiments, the suppression electrode is affixed to the ground electrode using upper and lower insulators. In some embodiments, the suppression electrode is affixed to the extraction plate using upper and lower insulators; and the ground electrode is affixed to the suppression electrode using ground electrode insulators. In some embodiments, the suppression electrode is a single conductive plate having an aperture therein.

According to another embodiment, a workpiece processing apparatus is disclosed. The workpiece processing apparatus comprises a plasma chamber having walls and an extraction plate with an extraction aperture; a ground electrode having a ground electrode aperture, physically connected to the extraction plate using ground electrode insulators; and a suppression electrode disposed between the ground electrode and the extraction plate; wherein the suppression electrode is movable relative to the extraction plate and the ground electrode. In some embodiments, the suppression electrode is movable in a height direction. In some embodiments, the suppression electrode is movable in a z-direction; such that a distance of a first gap between the extraction plate and the suppression electrode, and a distance of a second gap between the suppression electrode and the ground electrode are both variable. In some embodiments, the suppression electrode comprises an upper suppression plate and a lower suppression plate with an opening disposed therebetween. In certain embodiments, the upper suppression plate and the lower suppression plate are independently biased. In certain embodiments, the upper suppression plate and the lower suppression plate are independently movable.

### BRIEF DESCRIPTION OF THE FIGURES

For a better understanding of the present disclosure, reference is made to the accompanying drawings, which are incorporated herein by reference and in which:

FIG. 1 is a workpiece processing apparatus in accordance with one embodiment;

FIG. 2 is a perspective view of the extraction electrode assembly of FIG. 1;

FIG. 3 is a workpiece processing apparatus in accordance with another embodiment;

FIG. 4 is a perspective view of the extraction electrode assembly of FIG. 3; and

FIG. 5 is a workpiece processing apparatus in accordance with another embodiment.

### DETAILED DESCRIPTION

This disclosure describes systems that allow for the extraction of low energy ion beams. In some embodiments, the extraction voltage is 3kV or less. In other embodiments, the extraction voltage may be 2 kV or less. These systems may operate with extraction voltages as low as 0.1kV.

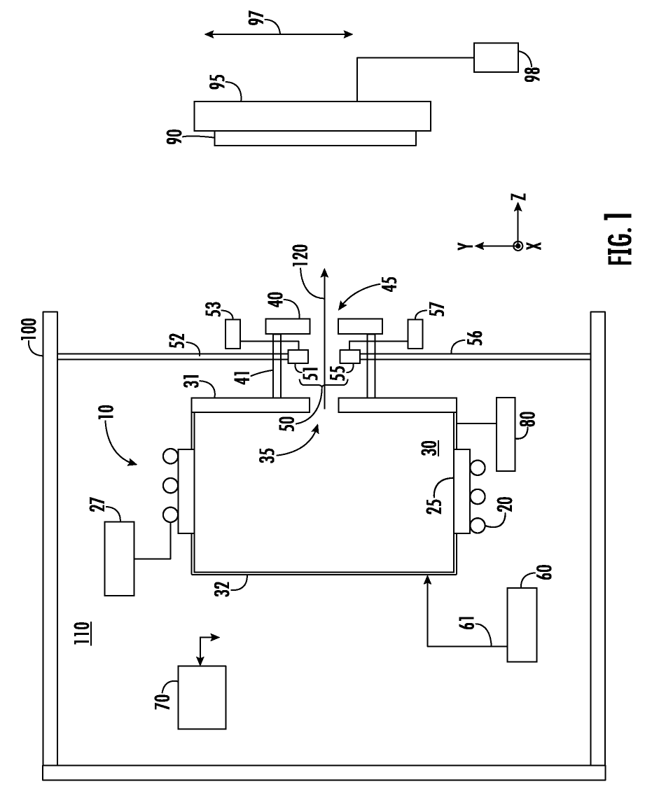

FIG. 1 shows a first embodiment of workpiece processing apparatus 10 for extracting a low energy ion beam. The workpiece processing apparatus 10 comprises a plasma chamber 30, which is defined by a plurality of chamber walls 32.

An antenna 20 is disposed external to the plasma chamber 30, proximate a dielectric window 25. The dielectric window 25 may also form one of the walls that define the plasma chamber 30. The antenna 20 is electrically connected to a RF power supply 27, which supplies an alternating voltage to the antenna 20. The voltage may be at a frequency of, for example, 2MHz or more. While the dielectric window 25 and antenna 20 are shown on opposite sides of the plasma chamber 30, other embodiments are also possible. For example, the antenna 20 may be disposed on the top of the plasma chamber 30. The chamber walls 32 of the plasma chamber 30 may be made of a conductive material, such as graphite. These chamber walls 32 may be biased at an extraction voltage, such as by extraction power supply 80. The extraction voltage may be, for example, 3kV or less, although other voltages are within the scope of the disclosure.

The workpiece processing apparatus 10 includes an extraction plate 31 having an extraction aperture 35. The extraction plate 31 may form another wall that defines plasma chamber 30. The extraction aperture 35 may be about 320 mm in the width direction (also referred to as the x-direction) and 3 mm in the height direction (also referred to as the y-direction), although other dimensions are possible. The extraction plate 31 may have a thickness in the z-direction of between 5 and 10 mm, although other dimensions are also possible. The z-direction is defined as perpendicular to both the x-direction and the y-direction and corresponds to the direction of travel of the extracted ion beam. This extraction plate 31 may be disposed on the side of the plasma chamber 30 adjacent to the dielectric window 25, although other configurations are also possible. In certain embodiments, the extraction plate 31 may be constructed of a conducting material.

In operation, the antenna 20 is powered using a RF signal from the RF power supply 27 so as to inductively couple energy into the plasma chamber 30. This inductively coupled energy excites the feed gas introduced from a gas storage container 60 via gas inlet 61, thus generating a plasma. While FIG. 1 shows an antenna and an RF power supply, other plasma generators may also be used with the present disclosure. For example, a capacitively coupled plasma generator may be used.

A controller 70 may be in communication with one or more of the power supplies, such as extraction power supply 80, RF power supply 27, upper suppression power supply 53 and lower suppression power supply 57, such that the voltage or current supplied by these power supplies may be monitored and/or modified. The controller 70 may include a processing unit, such as a microcontroller, a personal computer, a special purpose controller, or another suitable processing unit. The controller 70 may also include a non-transitory storage element, such as a semiconductor memory, a magnetic memory, or another suitable memory. This non-transitory storage element may contain instructions and other data that allows the controller 70 to perform the functions described herein.

The plasma within the plasma chamber 30 may be biased at the voltage being applied to the chamber walls 32 by the extraction power supply 80.

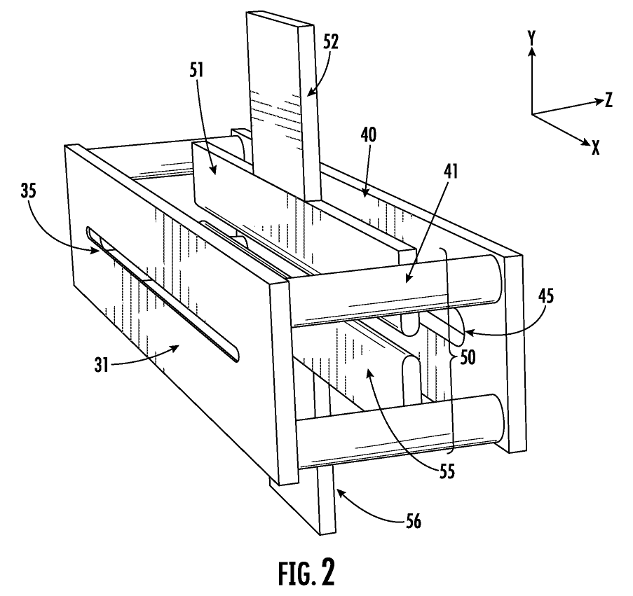

A ground electrode 40 is disposed outside the extraction plate 31 and is physically and rigidly affixed to the extraction plate 31 using ground electrode insulators 41. This is better illustrated in FIG. 2. The ground electrode 40 is electrically connected to ground. The ground electrode 40 may be a single conductive plate having a ground electrode aperture 45 therein. The size of this ground electrode aperture 45 may be larger than the size of the extraction aperture 35. Further, by physically and rigidly affixing the ground electrode 40 to the extraction plate 31, the ground electrode aperture 45 and the extraction aperture 35 are aligned in both the height and width directions. Thus, the positional accuracy of the ground electrode 40 relative to the extraction plate 31 is tightly controlled. As noted above, ground electrode insulators 41 may be used to affix the ground electrode 40 to the extraction plate 31. In some embodiments, there may be four ground electrode insulators 41 (see FIG. 2), two above the extraction aperture 35 and two below the extraction aperture 35. The ground electrode insulators 41 may be between 15 and 65 mm in length. Thus, the ground electrode insulators 41 define a fixed gap between the extraction plate 31 and the ground electrode 40 in the z-direction.

Between the extraction plate 31 and the ground electrode 40 is the suppression electrode 50. The suppression electrode 50 is implemented as two conductive plates; an upper suppression plate 51 and a lower suppression plate 55 with an opening disposed therebetween. Each plate is in communication with a respective power supply. Thus, the voltage of the upper suppression plate 51 is controlled by the upper suppression power supply 53, and the voltage of the lower suppression plate 55 is controlled by the lower suppression power supply 57. These two power supplies are independently controlled, such that the voltages applied to the two plates may differ. Like the ground electrode 40, the suppression electrode 50 is fixed in place. However, in this embodiment, the suppression electrode 50 is affixed to a different structure, such as a wall 100 of the vacuum chamber 110. In one embodiment, the upper suppression plate 51 is connected to a top wall of the vacuum chamber 110 using an upper insulator 52, while the lower suppression plate 55 is connected to a bottom wall of the vacuum chamber 110 using a lower insulator 56. Of course, in other embodiments, the suppression electrode 50 may be affixed to different surfaces. However, these surfaces are different from the extraction plate 31 and the ground electrode 40.

By affixing the suppression electrode 50 to a different surface, the insulative characteristics of the ground electrode insulator 41 may be relaxed. Specifically, the voltage difference between the ground electrode 40 and the extraction plate 31 is 3kV or less, and the separation distance is at least 15 mm. Meanwhile, the suppression electrodes may be biased at a negative voltage between -1kV and -25kV. By attaching these two plates to a different surface that may be further away, the insulative characteristics of the upper and lower insulators may be more easily achieved.

Note that since the upper suppression plate 51 and the lower suppression plate 55 are not secured to the extraction plate 31, it is possible that the opening between these two plates does not align perfectly with the extraction aperture 35 and the ground electrode aperture 45. For example, the opening may be slightly offset in the y-direction from the extraction aperture 35 and the ground electrode aperture 45. In this case, the voltages applied to the two plates may be slightly different to correct for this positioning error.

Further, the voltages applied to the plates may be more negative than the ground electrode 40 and may be as negative as -25kV.

The combination of the extraction plate 31, the suppression electrode 50 and the ground electrode 40 may collectively be referred to as the electrode assembly.

Further, the plates that comprise the suppression electrode 50 are fixed in place. Thus, the first gap, which is defined as the distance between the extraction plate 31 and the suppression electrode 50 in the z-direction, and the second gap, which is defined as the distance between the suppression electrode 50 and the ground electrode 40 in the z-direction, are fixed values. In some embodiments, the first gap may be between 5 and 30 mm, while the second gap may be between 5 and 30 mm. The size of the first gap and the second gap may be determined based on modeling, empirical testing or another method. Further, once determined, the electrode assembly may remain fixed in place.

Returning to FIG. 1, the workpiece 90, which may be disposed on a workpiece holder 95, is disposed outside the plasma chamber 30. The workpiece holder 95 may be a distance of 100 mm or more from the ground electrode 40. Further, the workpiece holder 95 may be grounded. A ribbon ion beam 120 is extracted from the electrode assembly which may be at least as wide as the workpiece 90 in one direction, such as the x-direction, and may be much narrower than the workpiece 90 in the orthogonal direction (or y-direction). In one embodiment, the extracted ribbon ion beam 120 may be about 10 mm in the y-direction and 320 mm in the x-direction.

Further, the workpiece holder 95 and workpiece 90 may be translated in the direction of travel 97 relative to the extraction aperture 35 such that different portions of the workpiece 90 are exposed to the ribbon ion beam 120. The process wherein the workpiece 90 is translated so that the workpiece 90 is exposed to the ribbon ion beam 120 is referred to as “a pass”. A pass may be performed by translating the workpiece holder 95 and workpiece 90 while maintaining the position of the plasma chamber 30. The speed at which the workpiece 90 is translated relative to the extraction aperture 35 may be referred to as workpiece scan velocity. In certain embodiments, the workpiece scan velocity may be about 100 mm/sec, although other speeds may be used. In another embodiment, the plasma chamber 30 may be translated while the workpiece 90 remains stationary. In other embodiments, both the plasma chamber 30 and the workpiece 90 may be translated. In some embodiments, the workpiece 90 moves at a constant workpiece scan velocity relative to the extraction aperture 35 in the y-direction, so that the entirety of the workpiece 90 is exposed to the ribbon ion beam 120 for the same amount of time.

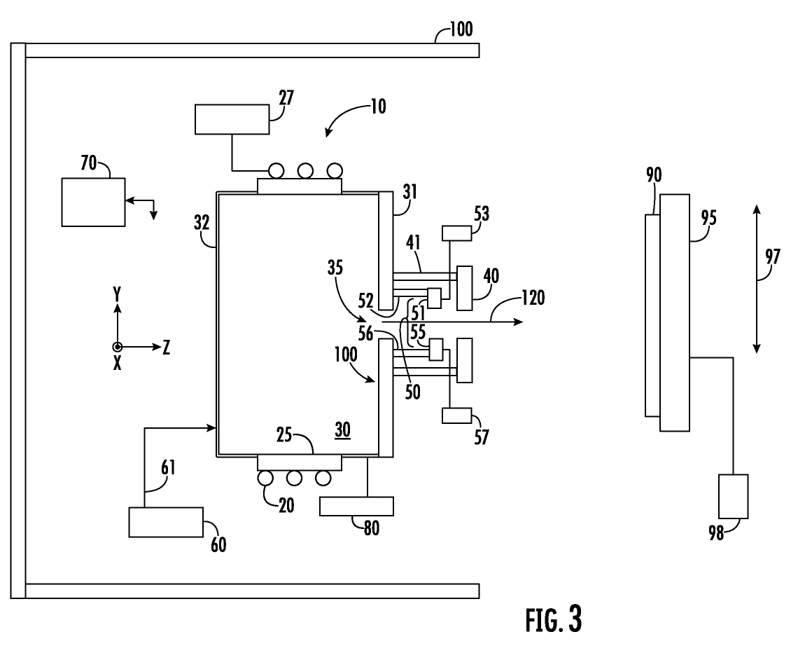

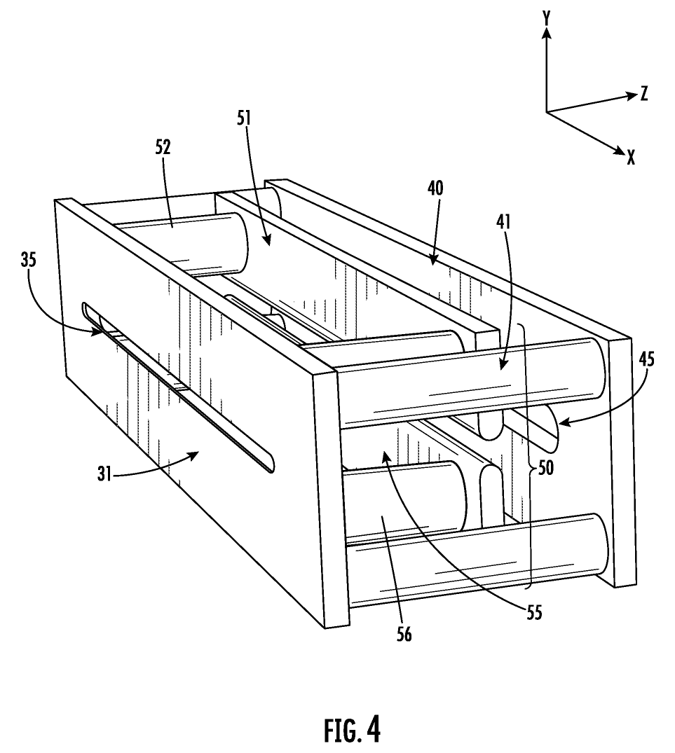

FIGS. 3 and 4 show a second embodiment of the workpiece processing apparatus 10. In this figure, like components that are also part of the workpiece processing system of FIG. 1 have been given identical reference designators. In this configuration, the upper insulator 52 and the lower insulator 56 have been modified to connect the upper suppression plate 51 and the lower suppression plate 55 directly to the extraction plate 31. These upper insulators 52 and lower insulators 56 establish a fixed spatial relationship between the extraction plate 31 and the suppression electrode 50. In this embodiment, while upper suppression power supply 53 and lower suppression power supply 57 are shown, it is possible that the upper suppression plate 51 and the lower suppression plate 55 may be biased using a common suppression power supply, since there is no possibility of positioning error in the y-direction. Additionally, if desired, the suppression electrode 50 may be a single conductive plate with a aperture therein, since the entire plate is commonly biased.

Note that the suppression electrode 50 and the ground electrode 40 may be held in place with a fixed relationship to the extraction plate 31 in other ways. For example, rather than having the upper insulator 52 and the lower insulator 56 affix the suppression electrode 50 directly to the extraction plate 31, these insulators may affix the suppression electrode 50 to the ground electrode 40, which, in turn, is affixed to the extraction plate 31. Alternatively, the upper insulator 52 and lower insulator 56 may be as shown in FIGS. 3-4, and the ground electrode insulators 41 may affix the ground electrode 40 to the suppression electrode 50.

The embodiments described above in the present application may have many advantages.

First, this configuration has no moving parts, which greatly reduces the complexity of the system. Further, by affixing the ground electrode 40 to the extraction plate 31, there is no risk of positioning error, which improves the beam angle spread.

For the embodiments shown in FIGS. 1-2, the attachment of the upper suppression plate 51 and lower suppression plate 55 to other surfaces (rather than the extraction plate 31 and the ground electrode 40), simplifies the design of the insulators. Additionally, by using two separate plates that may be independently biased, any positioning error in the height direction between the suppression electrode 50 and the extraction plate 31 may be easily corrected by separate biasing of the two plates. Additionally, this configuration allows operation using an extraction voltage of only 100V up to an extraction voltage of 3kV. Additionally, because of the separate attachment of the suppression electrode 50, the upper and lower plates of the suppression electrode may be biased to negative voltages may be as negative as -25kV.

In one simulation, a xenon ion beam was extracted at extraction voltages between 0.5kV and 2kV. In each simulation, the xenon beam had a beam current between 22mA to 30mA and a beam angle spread of less than 2°. The same suppression voltage (-7.5kV) was used for each extraction voltage. In another simulation, the extraction voltage was maintained at 1kV, while the suppression voltage was varied. By varying the suppression voltage from -2.4kV to -13.7kV, it was possible to extract a xenon ion beam having beam currents between about 5 mA and 50 mA or more with a beam angle spread of less than 2°.

Further, in another simulation, the suppression electrode 50 was offset from the extraction aperture 35 in the height direction by 1 mm. By proper independent biasing of the two suppression plates, it was possible to completely correct for this positioning error and achieve a beam with a beam angle spread of less than 2°.

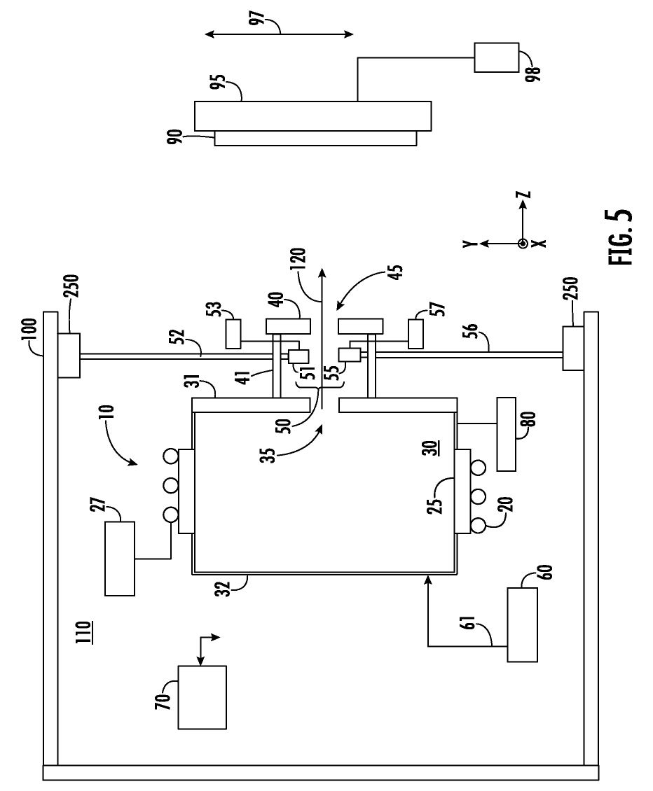

FIG. 5 shows another embodiment of the workpiece processing apparatus 10. In this embodiment, the ground electrode 40 may be affixed to the extraction plate 31 as described above using ground electrode insulators 41. The suppression electrode 50 may be movable relative to the ground electrode 40 and the extraction plate 31 in the height direction (the y-direction) and/or the z-direction. For example, as shown in FIG. 5, actuators 250 may be disposed proximate the walls of the vacuum chamber 110 to allow the upper suppression plate 51 and the lower suppression plate 55 to move in the z-direction and/or the y-direction.

Movement in the height direction may allow correction of positioning errors in the height direction. In certain embodiments, the two plates of the suppression electrode 50 may be independently movable. In other embodiments, the movement of the two plates may be coupled together so that they travel in unison. The plates may be commonly biased or independently biased in this embodiment. If the plates are to be commonly biased, they may be replaced with a single conductive plate with an aperture therein.

In another embodiment, the suppression electrode 50 may be movable relative to the ground electrode 40 and the extraction plate 31 in the z-direction. In this way, the first gap and the second gap may be modified as desired, while the distance from the ground electrode 40 to the extraction plate 31 remains constant. In other words, as the first gap is decreased, the second gap becomes larger. This may allow improved tuning of the extracted ion beam. The movement of the two plates may be coupled together so that they travel in unison.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A workpiece processing apparatus, comprising:
a plasma chamber having walls and an extraction plate with an extraction aperture;
a ground electrode having a ground electrode aperture, physically connected to the extraction plate using ground electrode insulators; and
a suppression electrode disposed between the ground electrode and the extraction plate; wherein the suppression electrode is affixed to a surface different from the extraction plate and the ground electrode; such that a distance of a first gap between the extraction plate and the suppression electrode, and a distance of a second gap between the suppression electrode and the ground electrode are both fixed.

2. The workpiece processing apparatus of claim 1, wherein the suppression electrode comprises an upper suppression plate and a lower suppression plate with an opening disposed therebetween.

3. The workpiece processing apparatus of claim 2, wherein the upper suppression plate and the lower suppression plate are independently biased.

4. The workpiece processing apparatus of claim 3, wherein a difference in voltage between the upper suppression plate and the lower suppression plate is used to correct for positioning errors in a height direction.

5. The workpiece processing apparatus of claim 2, wherein the plasma chamber is disposed within a vacuum chamber and wherein the upper suppression plate and the lower suppression plate are affixed to walls of the vacuum chamber.

6. The workpiece processing apparatus of claim 1, further comprising an extraction power supply to bias the walls of the plasma chamber, wherein a difference in voltage between the extraction plate and the ground electrode is defined as an extraction voltage and the extraction voltage is between 0.1kV and 3kV.

7. The workpiece processing apparatus of claim 6, wherein the suppression electrode is biased at a voltage between -1kV and -25kV.

8. A workpiece processing apparatus, comprising:
a plasma chamber having walls and an extraction plate with an extraction aperture;
a ground electrode having a ground electrode aperture, having a fixed spatial relationship to the extraction plate; and
a suppression electrode disposed between the ground electrode and the extraction plate; wherein the suppression electrode is affixed to one of the extraction plate and the ground electrode; such that a distance of a first gap between the extraction plate and the suppression electrode, and a distance of a second gap between the suppression electrode and the ground electrode are both fixed.

9. The workpiece processing apparatus of claim 8, wherein the ground electrode is affixed to the extraction plate using ground electrode insulators.

10. The workpiece processing apparatus of claim 9, wherein the suppression electrode is affixed to the extraction plate using upper and lower insulators.

11. The workpiece processing apparatus of claim 9, wherein the suppression electrode is affixed to the ground electrode using upper and lower insulators.

12. The workpiece processing apparatus of claim 8, wherein the suppression electrode is affixed to the extraction plate using upper and lower insulators; and the ground electrode is affixed to the suppression electrode using ground electrode insulators.

13. The workpiece processing apparatus of claim 8, wherein the suppression electrode is a single conductive plate having an aperture therein.

14. A workpiece processing apparatus, comprising:
a plasma chamber having walls and an extraction plate with an extraction aperture;
a ground electrode having a ground electrode aperture, physically connected to the extraction plate using ground electrode insulators; and
a suppression electrode disposed between the ground electrode and the extraction plate; wherein the suppression electrode is movable relative to the extraction plate and the ground electrode.

15. The workpiece processing apparatus of claim 14, wherein the suppression electrode is movable in a height direction.

16. The workpiece processing apparatus of claim 14, wherein the suppression electrode is movable in a z-direction; such that a distance of a first gap between the extraction plate and the suppression electrode, and a distance of a second gap between the suppression electrode and the ground electrode are both variable.

17. The workpiece processing apparatus of claim 14, wherein the suppression electrode comprises an upper suppression plate and a lower suppression plate with an opening disposed therebetween.

18. The workpiece processing apparatus of claim 17, wherein the upper suppression plate and the lower suppression plate are independently biased.

19. The workpiece processing apparatus of claim 17, wherein the upper suppression plate and the lower suppression plate are independently movable.
